(19) United States
(12) Patent Application Publication
(10) Pub. No.: US 2013/0014806 A1
(43) Pub. Date: Jan. 17, 2013

(54) WIRE ARRAY SOLAR CELLS EMPLOYING MULTIPLE JUNCTIONS

(71) Applicant: John IANNELLI, San Marino, CA (US)

(72) Inventor: John IANNELLI, San Marino, CA (US)

(73) Assignee: Caelux Corporation, Pasadena, CA (US)

(21) Appl. No.: 13/398,366

(22) Filed: Feb. 16, 2012

Related U.S. Application Data
(60) Provisional application No. 61/443,672, filed on Feb. 16, 2011.

(51) Int. Cl. H01L 31/0687; H01L 31/042

(52) U.S. Cl. 136/249; 136/244

(57) ABSTRACT

Wire array solar cells including tandem cells are disclosed. Each solar cell structure in the wire array can comprise a plurality of tandem cells, each tandem cell having multiple junctions separated by tunnel diodes. The junctions in the tandem cell have different bandgaps and are constructed to absorb different light spectra. Typically, each solar cell comprises an inner cell and an outer cell. The bandgap of the inner cell junction is constructed to be lower than the bandgap of the outer cell junction. The absorption and respective thicknesses of the inner and outer cell junctions is chosen so that the series current through the structure is matched in each cell and maximized.

### CROSS-REFERENCE TO RELATED APPLICATIONS

The present invention claims priority under 35 U.S.C. §119(e) to U.S. Provisional Application No. 61/443,672 filed on Feb. 16, 2011, entitled “Wire Array Solar Cells Employing Multiple Junctions,” which is incorporated herein by reference in its entirety.

### FIELD OF THE INVENTION

The present invention relates to wire array solar cells.

### BACKGROUND OF THE INVENTION

Wire array solar cell structures have the potential to be more efficient, when compared to planar solar cell structures, and can be a fraction of the cost of planar solar cell structures. Tandem cells are two junction devices that can have high efficiency by optimizing the cell absorption, the carrier collection, and the bandgaps of the two junctions. A more efficient wire array solar cell structure or a more effective tandem solar cell structure is desirable.

### SUMMARY OF THE INVENTION

One embodiment of the invention includes a substrate and a plurality of tandem cells on the substrate forming a wire array structure. In this embodiment, each tandem cell includes a first solar cell having a first junction of a first bandgap, and a second solar cell having a second junction of a second bandgap, the second solar cell covering at least a portion of the first solar cell. According to this embodiment, the second bandgap can be higher than the first bandgap. In some embodiments, a tunnel diode separates the second solar cell from the first solar cell. Each of the junctions can be formed in the axial or radial direction. In some embodiments, the first solar cell can be constructed of mono-crystalline silicon, poly-crystalline silicon, or micro-crystalline silicon. In addition, the second solar cell can be constructed of amorphous silicon, GaAsNP, CdSe, AIGaAs, InGaP, or compositions of Copper Indium Gallium Selenide (“CIGS”).

Another embodiment of the invention is an apparatus that also includes a substrate and a plurality of tandem cells on the substrate forming a wire array. In this embodiment, each tandem cell includes a first solar cell having a first junction of a first bandgap, a second solar cell having a second junction of a second bandgap, the second solar cell covering at least a portion of the first solar cell, and a third solar cell having a third junction of a third bandgap, the third solar cell covering at least a portion of the second solar cell. In some embodiments, a first tunnel diode separates the second solar cell from the first solar cell, and a second tunnel diode separates the third solar cell from the second solar cell.

Yet another embodiment of the invention is a wire array solar cell structure that includes a substrate and a plurality of tandem cells on the substrate. In this embodiment, each tandem cell includes a first solar cell having a first junction of a first bandgap, a first solar cell top surface and a first solar cell side surface forming a first solar cell cylinder, and a second solar cell having a second junction of a second bandgap, a second solar cell top surface and a second solar cell side surface forming a second solar cell cylinder, the second solar cell cylinder substantially covering the first solar cell cylinder. This embodiment can also include a third solar cell having a third junction of a third bandgap, a third solar cell top surface and a third solar cell side surface forming a third solar cell cylinder, the third solar cell cylinder substantially covering the second solar cell cylinder.

### BRIEF DESCRIPTION OF THE DRAWINGS

The present invention will be further understood and appreciated from the following detailed description taken in conjunction with the presented figure in which:

FIG. 1 is a perspective illustration of a wire array solar cell with multiple junctions according to embodiments of the present invention.

### DETAILED DESCRIPTION OF THE INVENTION

The present invention relates to wire array solar cells with multiple junctions. According to embodiments of the present invention, the efficiency of wire array solar cells is increased by incorporating multiple junctions in wire array solar cell structures. More specifically, according to some embodiments, the invention includes wire array solar cells, wherein each solar cell in the wire array comprises multiple junctions.

A conventional wire array solar cell typically forms a single junction in either the radial or the axial direction. The small dimensions of the wire, which can be sized on the order of the carrier diffusion or even less, results in minimized bulk recombination losses. Therefore, wire solar cell structures can use materials that were previously considered to have insufficient crystal quality to produce high efficiency solar cells from, for example, polycrystalline or amorphous materials. In such materials, the thickness must be sufficient to allow complete light absorption, but must be, at the same time, thin enough to enable complete carrier collection before recombination occurs. The combination of small dimension wires and multiple-pass light trapping can circumvent this trade-off and can result in improved performance.

Wire array solar cell structures can be efficiently concentrated because they have the advantage over planar solar cell structures of using less semiconductive material. An effective form of light trapping allows the majority of the incident light to be absorbed by a relatively small amount of semiconductor material. The efficient concentration increases the open-circuit voltage, and consequently increases the efficiency of the structure.

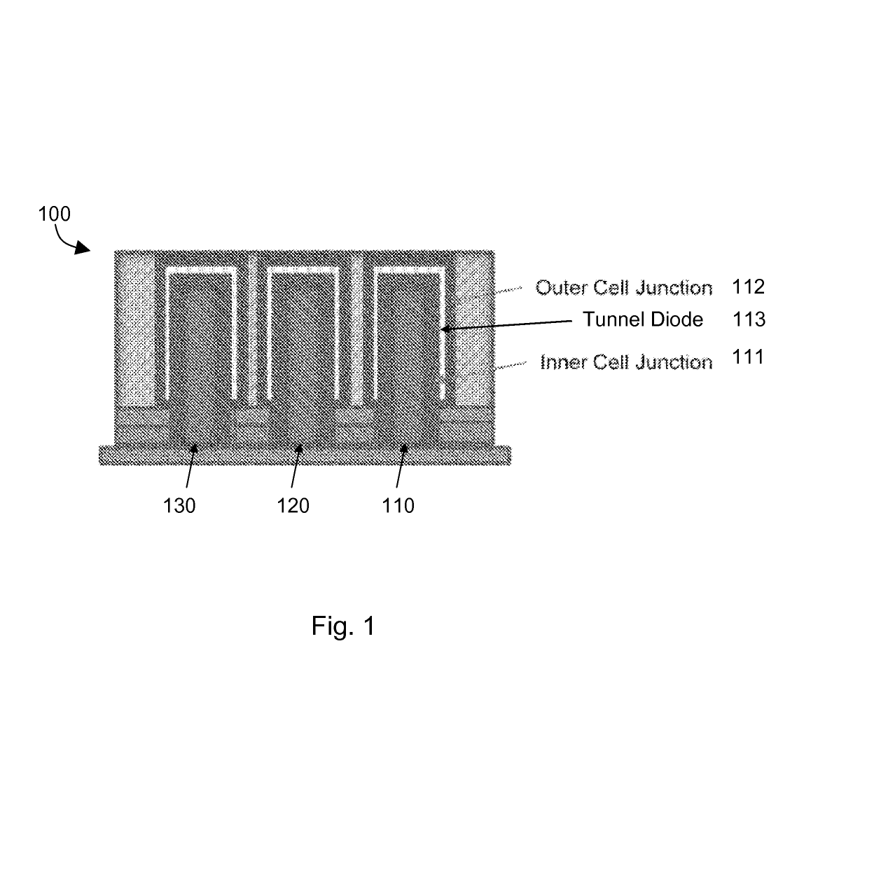

FIG. 1 shows a wire array solar cell 100 according to one embodiment of the invention. For purposes of illustration, the wire array solar cell 100 includes three tandem cells, e.g. tandem cell 110, tandem cell 120, and tandem cell 130. Each tandem cell 110, 120, 130 has an inner cell and an outer cell. The inner cell is constructed by a first junction and the outer cell is constructed by a second junction. For example, FIG. 1 shows tandem cell 110, with inner cell junction 111 and outer cell junction 112.

The inner and outer cell junctions 111, 112 have different bandgaps. In one embodiment, the bandgap of the inner cell junction 111 is constructed to be lower than the bandgap of the outer cell junction 112. For example, the bandgap of the inner cell junction 111 can be 1.1 eV and the bandgap of the outer cell junction 112 can be 1.7 eV. The material of the inner cell can be, for example, silicon, including but not limited to mono-crystalline silicon, poly-crystalline silicon, or micro-crystalline. The material of the outer cell can be, for example, amorphous silicon, GaAsNP, CdSe, AIGaAs, InGaP, or various compositions of Copper Indium Gallium Selenide (“CIGS”). The two junctions 111, 112 can be separated by a tunnel diode 113 that can be formed in either the upper or lower cell. The absorption and respective thicknesses of each junction can be chosen so that the series current through the structure is matched in each cell and is therefore maximized.

In one embodiment, a tandem solar cell structure with an inner cell of silicon and an outer cell of an amorphous material can result in high efficiency at a very low cost. Conventional amorphous silicon planar solar cells have the advantage of very high absorption coefficients, since the semiconductor has a direct bandgap versus crystalline silicon's indirect bandgap. However, the poor material quality of the amorphous state results in poor performance. The trade-off between carrier collection and absorption penalizes conventional amorphous silicon cells severely and efficiencies are in the range of 7-9%.

The wire array geometry can provide leverage for improving these efficiencies. Moreover, amorphous silicon solar cells suffer from a light-induced degradation known as the Stabler-Wronski effect, in which initial efficiencies drop by several percentage points before stabilizing. This effect is reduced as the absorption layer thickness is reduced. Therefore, the wire array solar cells that utilize amorphous silicon exhibit greatly reduced Stabler-Wronski degradation.

Amorphous silicon can absorb light with a spectrum of around 700 nm in wavelength and below. However, the efficiency of amorphous silicon drops significantly when absorbing this entire spectrum. A tandem solar cell addresses this inefficiency, by using i) an outer cell to absorb a portion of the light spectrum, for example, between 300-700 nm in wavelength, and ii) an inner cell to absorb a different portion of the light spectrum, for example, 700 nm in wavelength and above. Therefore, each cell can be constructed more efficiently and absorb light more efficiently.

In addition to a two junction tandem wire array solar cell, three- and four junction tandem wire array solar cells can be constructed within the scope of the invention.

Amorphous silicon is frequently used for solar cells. Amorphous silicon does not conduct current as efficiently as crystalline silicon. There is a trade-off when using amorphous silicon in solar cells. If the layer of amorphous silicon is too thin, it will not absorb enough light to be as effective as desired. However, if the layer of amorphous silicon is too thick, it will not generate current efficiently, which is also undesired. Solar cells typically use amorphous silicon layers of 250-300 nm in thickness. This thickness results in the best trade-off between light absorption and current-carrying efficiency.

The proposed wire array solar cell structure can use a much thinner layer of amorphous silicon than what is typically used. For example, the thickness of the amorphous silicon layer of the outer cell can range between 30-40 nm, instead of 250-300 nm. A single tandem cell with a thin-layered amorphous silicon outer cell does not have great light absorption properties. This, however, is compensated for with the wire array geometry, because light can be trapped with the wire cells of the array, enabling higher absorption compared to a single cell. Therefore, the thickness requirements of the outer cell in the wire array can be relaxed because of the wire array structure. This allows for flexibility in the selection of the inner and outer cell thicknesses when designing the tandem cell.

FIG. 1 shows a wire array structure that includes a row including tandem cell 110, tandem cell 120, and tandem cell 130. It should be realized that a wire array structure can include another row or rows of tandem cells adjacent these three tandem cells 110, 120, 130; e.g., an array of cells. In addition, FIG. 1 shows a wire array structure that includes three tandem cells, but the wire array structure according to the invention can include a large or smaller number of tandem cells in each row of the array.

The wire array solar cells according to the invention can be formed in a variety of ways, including by a chemical vapor deposition (CVD) process on a substrate. The substrate can be, for example, a native semiconductive material or an insulating material, for example, glass or quartz. The wires typically grow in the vertical direction with a given spacing or pitch among them.

While the invention has been described with respect to a limited number of embodiments, it will be appreciated that many variations, modifications and other applications of the invention may be made. It will further be appreciated that the invention is not limited to what has been described hereinabove merely by way of example. Rather, the invention is limited solely by the claims which follow.

What is claimed is:

1. An apparatus comprising:
a substrate; and
a plurality of tandem cells on the substrate forming a wire array structure, each tandem cell comprising:
a first solar cell having a first junction of a first bandgap; and
a second solar cell having a second junction of a second bandgap, the second solar cell covering at least a portion of the first solar cell.

2. The apparatus of claim 1, each tandem cell further comprising a tunnel diode separating the second solar cell from the first solar cell.

3. The apparatus of claim 1, wherein the second bandgap is higher than the first bandgap.

4. The apparatus of claim 1, wherein the first solar cell further has a first solar cell top surface and a first solar cell side surface forming a first solar cell cylinder; and
wherein the second solar cell further has a second solar cell top surface and a second solar cell side surface forming a second solar cell cylinder, the second solar cell cylinder substantially covering the first solar cell cylinder.

5. The apparatus of claim 1, wherein the first bandgap is 1.1 eV and the second bandgap is 1.7 eV.

6. The apparatus of claim 1, wherein the first solar cell is constructed of at least one of mono-crystalline silicon, poly-crystalline silicon, and micro-crystalline silicon.

7. The apparatus of claim 1, wherein the second solar cell is constructed of at least one of amorphous silicon, GaAsNP, CdSe, AIGaAs, InGaP, and compositions of Copper Indium Gallium Selenide (“CIGS”).

8. The apparatus of claim 1, wherein the first junction is formed in a radial direction.

9. The apparatus of claim 1, wherein the first junction is formed in an axial direction.

10. The apparatus of claim 1, wherein the second junction is formed in a radial direction.

11. The apparatus of claim 1, wherein the second junction is formed in an axial direction.

12. The apparatus of claim 1, wherein the tunnel diode is formed in the first solar cell.

13. The apparatus of claim 1, wherein the tunnel diode is formed in the second solar cell.

14. An apparatus comprising:
a substrate; and
a plurality of tandem cells on the substrate forming a wire array, each tandem cell comprising:
a first solar cell having a first junction of a first bandgap;
a second solar cell having a second junction of a second bandgap, the second solar cell covering at least a portion of the first solar cell; and
a third solar cell having a third junction of a third bandgap, the third solar cell covering at least a portion of the second solar cell.

15. The apparatus of claim 14, each tandem cell further comprising:
a first tunnel diode separating the second solar cell from the first solar cell; and
a second tunnel diode separating the third solar cell from the second solar cell.

16. The apparatus of claim 14, wherein the second bandgap is higher than the first bandgap.

17. The apparatus of claim 14, wherein the first solar cell further has a first solar cell top surface and a first solar cell side surface forming a first solar cell cylinder;
wherein the second solar cell further has a second solar cell top surface and a second solar cell side surface forming a second solar cell cylinder, the second solar cell cylinder substantially covering the first solar cell cylinder; and
wherein the third solar cell further has a third solar cell top surface and a third solar cell side surface forming a third solar cell cylinder, the third solar cell cylinder substantially covering the second solar cell cylinder.

18. The apparatus of claim 14, wherein each tandem cell further comprises a fourth solar cell having a fourth junction of a fourth bandgap, the fourth solar cell covering at least a portion of the third solar cell.

19. The apparatus of claim 18, wherein the first solar cell further has a first solar cell top surface and a first solar cell side surface forming a first solar cell cylinder;
wherein the second solar cell further has a second solar cell top surface and a second solar cell side surface forming a second solar cell cylinder, the second solar cell cylinder substantially covering the first solar cell cylinder;
wherein the third solar cell further has a third solar cell top surface and a third solar cell side surface forming a third solar cell cylinder, the third solar cell cylinder substantially covering the second solar cell cylinder; and
wherein the fourth solar cell further has a fourth solar cell top surface and a fourth solar cell side surface forming a fourth solar cell cylinder, the fourth solar cell cylinder substantially covering the third solar cell cylinder.

20. A wire array solar cell structure comprising:
a substrate; and
a plurality of tandem cells on the substrate, each tandem cell comprising:
a first solar cell having a first junction of a first bandgap, a first solar cell top surface and a first solar cell side surface forming a first solar cell cylinder; and
a second solar cell having a second junction of a second bandgap, a second solar cell top surface and a second solar cell side surface forming a second solar cell cylinder, the second solar cell cylinder substantially covering the first solar cell cylinder.

21. The apparatus of claim 20, wherein the second bandgap is higher than the first bandgap.

22. A wire array solar cell structure comprising:
a substrate; and
a plurality of tandem cells on the substrate, each tandem cell comprising:
a first solar cell having a first junction of a first bandgap, a first solar cell top surface and a first solar cell side surface forming a first solar cell cylinder;
a second solar cell having a second junction of a second bandgap, a second solar cell top surface and a second solar cell side surface forming a second solar cell cylinder, the second solar cell cylinder substantially covering the first solar cell cylinder; and
a third solar cell having a third junction of a third bandgap, a third solar cell top surface and a third solar cell side surface forming a third solar cell cylinder, the third solar cell cylinder substantially covering the second solar cell cylinder.

23. The wire array solar cell structure of claim 22, each tandem cell further comprising a fourth solar cell having a fourth junction of a fourth bandgap, a fourth solar cell top surface and a fourth solar cell side surface forming a fourth solar cell cylinder, the fourth solar cell cylinder substantially covering the third solar cell cylinder.
